(19) United States
(12) Patent Application Publication
(10) Pub. No.: US 2025/0216800 A1
(43) Pub. Date: Jul. 3, 2025

(54) AIR CONDITIONER AND SUBSTRATE TREATING APPARATUS INCLUDING THE SAME

(71) Applicant: SEMES CO., LTD., Cheonan-si (KR)

(72) Inventors: Sang Hoon LEE, Pyeongtaek-si (KR); Ju Yeon CHO, Suwon-si (KR); Jin Taek OH, Asan-si (KR); Si Hwan YANG, Osan-si (KR); Hyeon Ho KIM, Pyeongtaek-si (KR); Woo Ram LEE, Seoul (KR); Young Un YUN, Asan-si (KR); Won Kwon SHIN, Cheonan-si (KR)

(73) Assignee: SEMES CO., LTD., Cheonan-si (KR)

(21) Appl. No.: 18/976,951

(22) Filed: Dec. 11, 2024

(30) Foreign Application Priority Data
Dec. 27, 2023 (KR) 10-2023-0193410

(51) Int. Cl. G03F 7/00

(52) U.S. Cl. CPC G03F 7/70858

(57) ABSTRACT

Disclosed is an air conditioning device for providing downward airflow from an upper portion of a process chamber having a treatment space in which a first treating unit and a second treating unit are disposed side by side to the treatment space, the air conditioning device including: a case having an inlet through which air is introduced at one side, and having an opening at a lower surface for the air introduced through the inlet to flow downwardly; and an internal duct for guiding air from the inlet to a center of the case such that the air introduced through the inlet is uniformly supplied to an interior space of the case.

### CROSS-REFERENCE TO RELATED APPLICATIONS

This application claims priority to and the benefit of Korean Patent Application No. 10-2023-0193410 filed in the Korean Intellectual Property Office on Dec. 27, 2023, the entire contents of which are incorporated herein by reference.

### TECHNICAL FIELD

The present invention relates to a substrate treating apparatus for treating a substrate.

### BACKGROUND ART

In general, various processes, such as cleaning, deposition, photolithography, etching, and ion implantation, are performed to manufacture semiconductor devices. The photolithography process, which is performed to form patterns, plays an important role in achieving high integration of semiconductor devices.

The photolithography process is performed to form photoresist patterns on semiconductor substrates made of silicon. The photolithography process includes a coating and soft bake process to form a photoresist film on the substrate, an exposure and development process to form a photoresist pattern from the photoresist film, an Edge Bead Removal (EBR) process and an Edge Exposure of wafer (EEW) process to remove edge areas of the photoresist film or pattern, and a hard bake process for stabilizing and densifying the photoresist pattern.

Among the substrate treating apparatuses that perform the photolithography processes, a multi-unit arrangement method in which multiple treating units are arranged in a single chamber is used, and in a multi-unit arrangement substrate treating apparatus, an air conditioning device, such as a Filter Unit (FU), is installed in the upper portion of the chamber, and substrate treatment is performed in a state of downflow of air from the air conditioning device.

However, in the current gas supply structure of the filter unit, gas is eccentrically supplied and passes through the filter, so that the airflow is diverted vertically, and in this case, temperature deviations occur due to the heating elements present in the other process chamber located at the top of the filter unit. This causes the environmental temperature in the process chamber located at the bottom of the filter unit to deviate. This causes thickness deviation due to environmental temperature deviation after substrate treatment.

### SUMMARY OF THE INVENTION

The present invention has been made in an effort to provide an air conditioning device capable of evenly distributing gas supplied from one side up, down, left and right, and a substrate treating apparatus including the same.

The present invention has also been made in an effort to provide an air conditioning device capable of minimizing temperature influence in a periphery region, and a substrate treating apparatus including the same.

The present invention has also been made in an effort to provide an air conditioning device capable of providing airflow of uniform temperature to a process chamber in which a substrate treating unit is arranged, and a substrate treating apparatus including the same.

The object of the present invention is not limited thereto, and other objects not mentioned will be clearly understood by those of ordinary skill in the art from the following description.

An exemplary embodiment of the present invention provides an air conditioning device for providing downward airflow from an upper portion of a process chamber having a treatment space in which a first treating unit and a second treating unit are disposed side by side to the treatment space, the air conditioning device including: a case having an inlet through which air is introduced at one side, and having an opening at a lower surface for the air introduced through the inlet to flow downwardly; and an internal duct for guiding air from the inlet to a center of the case such that the air introduced through the inlet is uniformly supplied to an interior space of the case.

Further, the internal duct may include a central duct dividing the interior space of the case into a first space and a second space and supplying air to the first space and the second space.

Further, the central duct may include a first partition wall that is in contact with the first space and a second partition wall that is in contact with the second space, and the first partition wall and the second partition wall may be made of perforated plates.

Further, the first space may be located on top of the first treating unit, and the second space may be located on top of the second treating unit.

Further, the first space and the second space may have spaces symmetric with respect to the central duct.

Further, the air conditioning device may further include an upper air pocket provided on a top surface of the case.

Further, the air conditioning device may further include lateral air pockets provided on both lateral surfaces of the case.

Further, the air conditioning device may further include: a plate-shaped filter installed in the opening; and a perforated plate installed at a bottom end of the filter.

Another exemplary embodiment of the present invention provides a substrate treating apparatus including: a chamber having a treatment space; a first treating unit and a second treating unit arranged in line along a first direction in the treatment space of the chamber; and an air conditioning device installed in an upper portion of the chamber, and providing downflow airflow into the treatment space of the chamber,

Further, the internal duct may include a central duct dividing the interior space of the case into a first space and a second space and supplying air to the first space and the second space.

Further, the central duct may include a first partition wall that is in contact with the first space and a second partition wall that is in contact with the second space, and the first partition wall and the second partition wall may be made of perforated plates.

Further, the first space may be located on top of the first treating unit, and the second space may be located on top of the second treating unit.

Further, the first space and the second space may have spaces symmetric with respect to the central duct.

Further, the substrate treating apparatus may further include an upper air pocket provided on a top surface of the case.

Further, the substrate treating apparatus may further include lateral air pockets provided on both lateral surfaces of the case.

Further, the substrate treating apparatus may further include: a plate-shaped filter installed in the opening; and a perforated plate installed at a bottom end of the filter.

Further, the first treating unit and the second treating unit may apply a liquid to the substrate.

Further, the chambers are staked in plural.

Still another exemplary embodiment of the present invention provides a substrate treating apparatus including: a chamber having a treatment space; a first treating unit and a second treating unit arranged in line along a first direction in the treatment space of the chamber, and applying a liquid to a substrate; and an air conditioning device installed in an upper portion of the chamber, and providing downflow airflow into the treatment space of the chamber, in which the air conditioning device includes: a case having an inlet through which air is introduced at one side, and having an opening at a lower surface for the air introduced through the inlet to flow downwardly; an internal duct for guiding the air from the inlet to a center of the case such that the air introduced through the inlet is uniformly supplied to an interior space of the case; a plate-shaped filter installed in the opening; a perforated plate installed at a bottom end of the filter; an upper air pocket provided on a top surface of the case; and lateral air pockets provided on both lateral surfaces of the case, and the internal ducting includes a central duct that divides the interior space of the case into a first space located on top of the first treating unit and a second space located on top of the second treating unit and that supplies air to the first space and the second space.

Further, the central duct may include a first partition wall that is in contact with the first space and a second partition wall that is in contact with the second space, the first partition wall and the second partition wall may be made of perforated plates, and the first space and the second space may have spaces symmetric with respect to the central duct.

According to the exemplary embodiment of the present invention, air supplied through the inlet may be diffused from the center of the case to the first space and the second space through the internal duct formed inside the case to provide uniform airflow to the treatment space.

According to the exemplary embodiment of the present invention, by configuring the air pockets on the top surface and both lateral surfaces of the case, it is possible to minimize the temperature influence caused by the heating elements in the periphery to supply air with a uniform temperature to the treatment space.

According to the exemplary embodiment of the present invention, air is supplied from the center of the case to the first space and the second space and flows downwardly into the liquid treating chamber, and in particular, the heat transferred to the top surface and lateral surfaces of the case is blocked by the air pockets, so that temperature equalization may be expected when air is supplied to the liquid treating chamber.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

FIG. 1 is a perspective view schematically illustrating a substrate treating apparatus according to an exemplary embodiment of the present invention.

FIG. 2 is a front view of the substrate treating apparatus of FIG. 1.

FIG. 3 is a top plan view of an applying block in the substrate treating apparatus of FIG. 1.

FIG. 4 is a top plan view of a developing block in the substrate treating apparatus of FIG. 1.

FIG. 5 is a top plan view schematically illustrating a transfer robot of FIG. 3.

FIG. 6 is a top plan view schematically illustrating one example of a heat treating chamber of FIG. 3 or FIG. 4.

FIG. 7 is a cross-sectional view of the heat treating chamber of FIG. 6.

FIG. 8 is a cross-sectional view illustrating an exemplary embodiment of a liquid treating chamber.

FIG. 9 is a top view of the liquid treating chamber of FIG. 8.

FIG. 10 is a perspective view illustrating an example of air conditioning devices installed in stacked liquid treating chambers.

FIG. 11 is a perspective view of the air conditioning device illustrated in FIG. 10.

FIGS. 12 and 13 are a top plan view and a lateral cross-sectional view of the air conditioning device.

FIG. 14 is a perspective view of an internal duct illustrated in FIG. 12.

FIG. 15 is a lateral cross-sectional view illustrating an example of the air conditioning devices installed in stacked liquid treating chambers.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer will be described as an example of an object to be processed. However, the technical spirit of the present invention may be applied to devices used for other types of substrate treatment, in addition to wafers.

Hereinafter, exemplary embodiments of the present invention will be described with reference to the accompanying drawings.

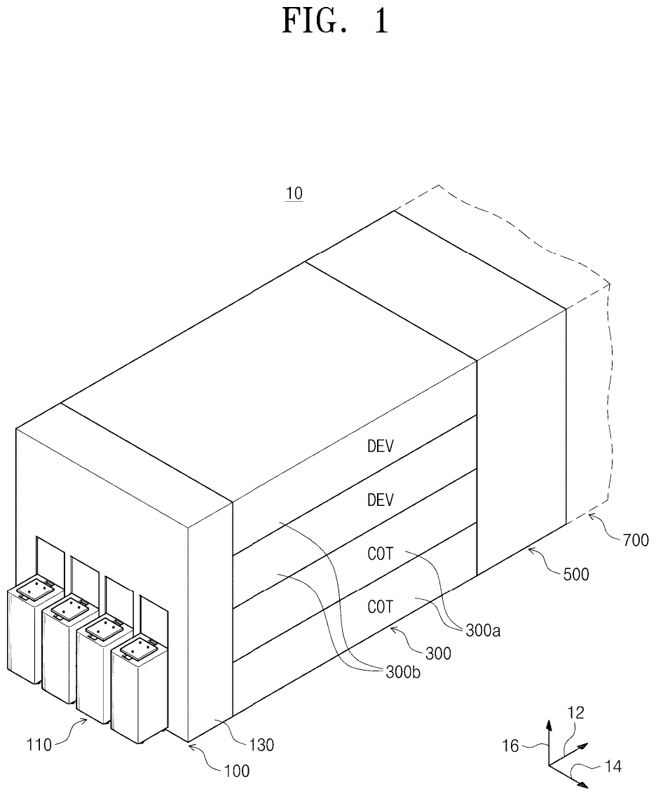

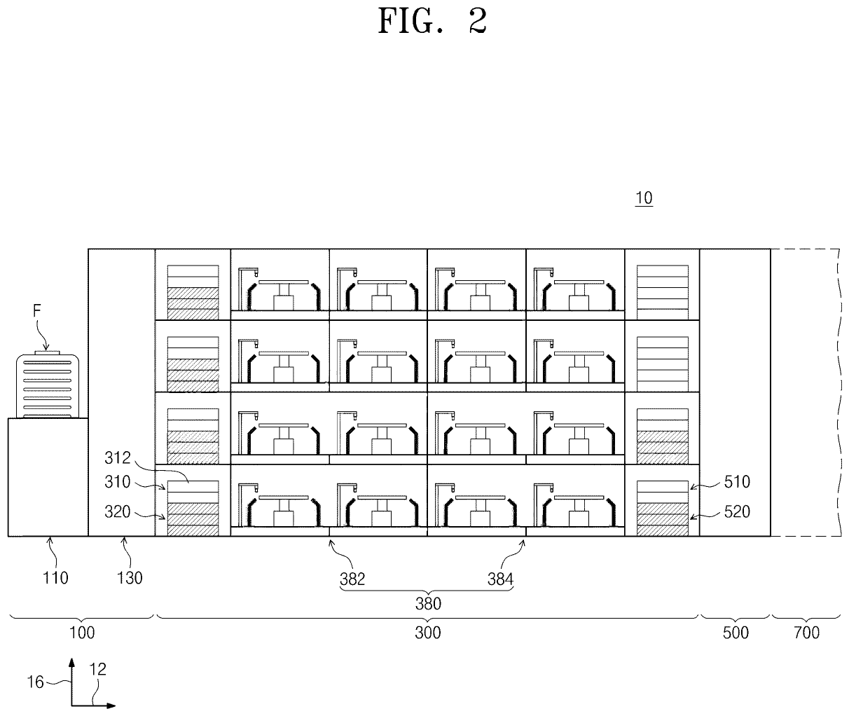

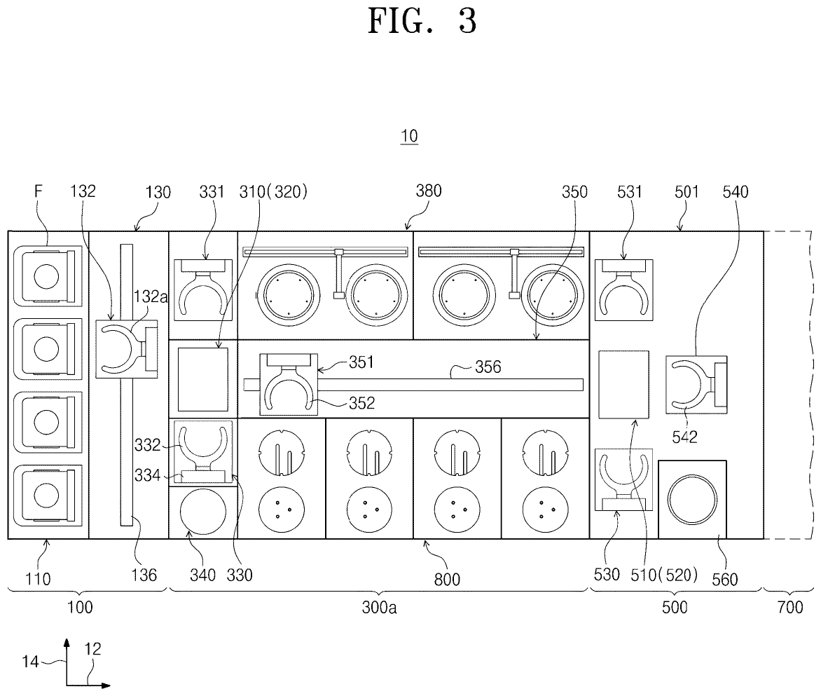

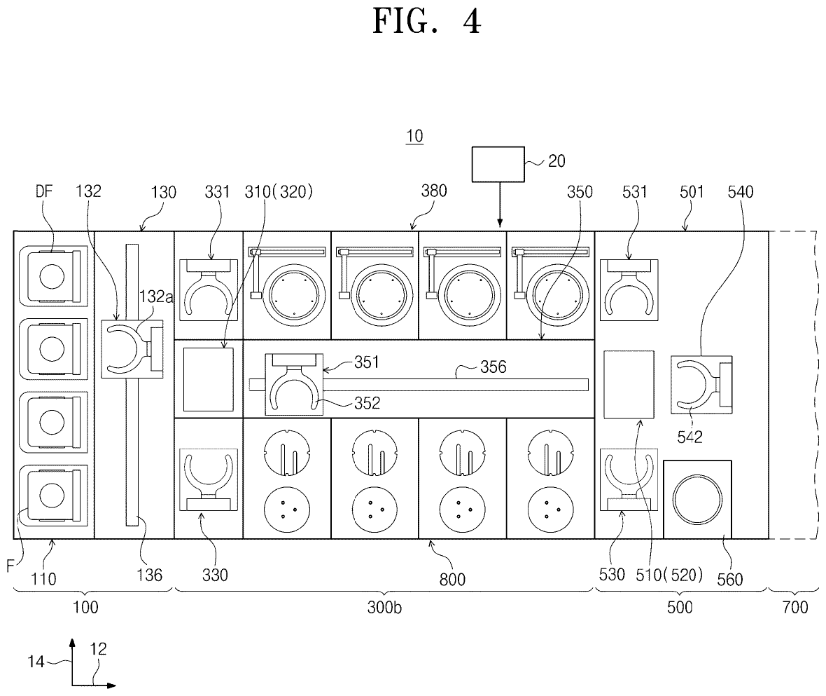

FIG. 1 is a perspective view schematically illustrating a substrate treating apparatus according to an exemplary embodiment of the present invention, and FIG. 2 is a front view of the substrate treating apparatus of FIG. 1. FIG. 3 is a top plan view of an applying block in the substrate treating apparatus of FIG. 1, and FIG. 4 is a top plan view of a developing block in the substrate treating apparatus of FIG. 1.

Referring to FIGS. 1 to 4, a substrate treating apparatus 10 includes an index module 100, a treating module 300, and an interface module 500. According to the exemplary embodiment, the index module 100, the treating module 300, and the interface module 500 are sequentially arranged in a row. Hereinafter, a direction in which the index module 100, the treating module 300, and the interface module 500 are arranged is referred to as a first direction 12, a direction perpendicular to the first direction 12 when viewed from above is referred to as a second direction 14, and a direction perpendicular to the first direction 12 and the second direction 14 is referred to as a third direction 16.

The index module 100 is provided for transferring a substrate W between a container F in which the substrate W is accommodated and the treating module 300. A longitudinal direction of the index module 100 is provided in the second direction 14. The index module 100 includes a load port 110 and an index frame 130. The container F in which the substrates W are accommodated is placed on the load port 110. The load port 110 is located on the opposite side of the treating module 300 with respect to the index frame 130. A plurality of load ports 110 may be provided, and the plurality of load ports 110 may be disposed along the second direction 14. Any one of the plurality of load ports 110 may be provided with a dummy container DF containing a dummy substrate. The dummy substrates accommodated in the dummy container DF may be used for cleaning the drying chamber.

In an example, as the container F, an airtight container F, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided inside the index frame 130. Within the index frame 130, a guide rail 136 is provided. A longitudinal direction of the guide rail 136 is provided in the second direction 14. The index robot 132 is mounted on the guide rail 136 so as to be movable along the guide rail 136. The index robot 132 includes a hand 132a on which the substrate W is placed. The hand 132a may be provided to be movable forward and backward, movable linearly along the third direction, and rotatably movable about the third direction 16 as the axis.

The treating module 300 performs an application process and a development process on the substrate W. The treating module 300 includes an applying block 300a and a developing block 300b.

The applying block 300a performs an application process on the substrate W before the exposure process. The developing block 300b performs a development process on the substrate W after the exposure process. A plurality of applying blocks 300a is provided. The plurality of applying blocks 300a may be provided while being stacked on top of each other. A plurality of developing blocks 300b is provided. The plurality of developing blocks 300b may be provided to be stacked with each other. In one example, two applying blocks 300a are provided and two developing blocks 300b are provided. The plurality of applying blocks 300a may be located below the developing blocks 300b.

In one example, the plurality of applying blocks 300a may be provided with structures that are identical to each other. A film applied to the substrate W in each of the plurality of applying blocks 300a may be the same type of film. Optionally, the films applied to the substrate W by each applying block 300a may be different types of films. The film applied to the substrate W includes a photoresist film. The film applied to the substrate W may further include an anti-reflective film. Optionally, the film applied to the substrate W may further include a protective film.

Additionally, the two developing blocks 300b may be provided with the same structures as each other. A developer supplied to the substrate W in the plurality of developing blocks 300b may be the same type of liquid. Optionally, the developer supplied to the substrate W may be different types of developer depending on the developing blocks 300b. For example, a process for removing a light-irradiated region in a region of a register film on the substrate W may be performed in one of the two developing blocks 300b, and a process for removing a non-irradiated region may be performed in the other of the two developing blocks 300b.

Referring to FIG. 3, the applying block 300a includes a buffer unit 310, a cooling unit 320, a hydrophobization chamber 340, a transfer chamber 350, a heat treating chamber 800, and a liquid treating chamber 380.

The buffer unit 310, the cooling unit 320, and the hydrophobization chamber 340 are disposed adjacent to the index module 100. The hydrophobization chamber 340 and the buffer unit 310 may be sequentially disposed along the second direction 14. In addition, the cooling unit 320 and the buffer unit 310 may be provided to be stacked on top of each other in a vertical direction.

The buffer unit 310 includes one or a plurality of buffers 312. When a plurality of buffers 312 is provided, the plurality of buffers 312 may be arranged to be stacked on top of each other. The buffer 312 provides a space for the substrate W to stay when the substrate W is transferred between the index module 100 and the treating module 300. The hydrophobization chamber 340 provides a hydrophobization treatment to the surface of the substrate W. The hydrophobization treatment may be performed prior to performing an application process on the substrate W. The hydrophobization treatment may be accomplished by supplying hydrophobizing gas to the substrate W while heating the substrate W. The cooling unit 320 cools the substrate W. The cooling unit 320 includes one or more cooling plates. When a plurality of cooling plates is provided, the plurality of cooling plates may be arranged to be stacked on top of each other. In one example, the cooling unit 320 may be disposed below the buffer unit 310. The cooling plate may have a flow path through which coolant flows. The substrate W after the hydrophobization treatment may be cooled on the cooling plate.

A transfer mechanism 330 is provided between the hydrophobization chamber 340 and the buffer unit 310 and between the hydrophobization chamber 340 and the cooling unit 320. The transfer mechanism 330 is provided for transferring the substrate W between the buffer unit 310, the hydrophobization chamber 340, and the cooling unit 320.

The transfer mechanism 330 includes a hand 332 on which the substrate W is placed, and the hand 332 may be provided to be movable forward and backward, rotatable about the third direction 16 as the axis, and movable along the third direction 16. In one example, the transfer mechanism 330 is moved in the third direction 16 along the guide rail 334. The guide rail 334 extends from an applying block located at the lowest of the applying blocks 300a to a developing block located at the highest of the developing blocks 300b. This allows the transfer mechanism 330 to transfer the substrate W between the blocks 300a and 300b provided on different layers. For example, the transfer mechanism 330 may transfer the substrate W between the applying blocks 300a and 300b provided on different layers. The transfer mechanism 330 may also transfer the substrate W between the applying block 300a and the developing block 300b.

In addition, another transfer unit 331 may be further provided on the opposite side of the side where the hydrophobization chamber 340 is provided with respect to the buffer unit 310. Another transfer unit 331 may be provided to transfer the substrate W between the buffer unit 310 and the cooling unit 320 provided in the same block 300a and 300b. Further, another transfer unit 331 may be provided to transfer the substrate W between the buffer unit 310 and the cooling unit 320 provided in different blocks 300a and 300b.

The transfer chamber 350 is provided with its longitudinal direction parallel to the first direction 12. One end of the transfer chamber 350 may be located adjacent to the buffer unit 310 and/or the cooling unit 320. The other end of the transfer chamber 350 may be located adjacent to the interface module 500.

A plurality of heat treating chambers 800 is provided. Some of the heat treating chambers 800 are disposed along the first direction 12. Additionally, some of the heat treating chambers 800 may be stacked along the third direction 16. The heat treating chambers 800 may all be located on one side of the transfer chamber 350.

In one example, the liquid treating chamber 380 has a multi-unit arrangement with multiple applying units disposed in a single chamber. The liquid treating chamber 380 of the multi-unit arrangement has an air conditioning device 900 installed at the top, and performs the process in a state of downflow of air from the air conditioning device 900.

The liquid treating chamber 380 performs a liquid film formation process to form a liquid film on the substrate W. In one example, the liquid film forming process includes a resist film forming process. The liquid film forming process may include an anti-reflective film forming process. Optionally, the liquid film forming process may further include a protective film forming process. A plurality of liquid treating chambers 380 is provided. The liquid treating chambers 380 may be located on opposite sides of the heat treating chamber 800. For example, all of the liquid treating chambers 380 may be located on the other side of the transfer chamber 350. The liquid treating chambers 3600 are arranged side by side in the first direction 12. Optionally, some of the liquid treating chambers 800 may be stacked along the third direction 16.

In one example, the liquid treating chambers 380 include a front end liquid treating chamber 382 and a rear end liquid treating chamber 384. The front end liquid treating chamber 382 is disposed relatively close to the index module 100, and the rear end liquid treating chamber 384 is disposed more close to the interface module 500.

The front end liquid treating chamber 382 applies a first liquid onto the substrate W, and the rear end liquid treating chamber 384 applies a second liquid onto the substrate W. The first liquid and the second liquid may be different types of liquid. In one example, the first liquid may be a liquid for forming an anti-reflective film and the second liquid may be a liquid for forming a photoresist film. The photoresist film may be formed on a substrate W to which an anti-reflective film has been applied. Optionally, the first liquid may be a liquid for forming a photoresist film, and the second liquid may be a liquid for forming an antireflective film. In this case, the anti-reflective film may be formed on the substrate W on which the photoresist film is formed. Optionally, the first liquid and the second liquid may be the same kind of liquid, and they may both be liquids for forming the photoresist film.

Referring to FIG. 4, the developing block 300b includes a buffer unit 310, a cooling unit 320, a transfer chamber 350, a heat treating chamber 800, a drying chamber 600, and a liquid treating chamber 380.

The arrangement of the buffer unit 310, the cooling unit 320, the transfer chamber 350, the heat treating chamber 800, and the liquid treating chamber 380 in the developing block 300b may be the same as the arrangement of the buffer unit 310, the cooling unit 320, the transfer chamber 350, the heat treating chamber 800, and the liquid treating chamber 380 in the applying block 300a. When viewed from above, the buffer unit 310, the cooling unit 320, the transfer chamber 350, the heat treating chamber 800, and the liquid treating chamber 380 in the developing block 300b and the buffer unit 310, the cooling unit 320, the transfer chamber 350, the heat treating chamber 800, and the liquid treating chamber 380 in the applying block 300 may be disposed in overlapping positions.

The heat treating chamber 800 performs a heating process on the substrate W. The heating process includes a post-exposure baking process performed on the substrate W after the exposure process is completed, and a hard baking process performed on the substrate W after the development process is completed.

Additionally, the heat treating chamber 800 performs a heating process on the dummy substrate DW. The heating process for the dummy substrate DW includes a baking process for the dummy substrate DW used for cleaning the drying chamber 600. The dummy substrate DW may be baked in the heat treating chamber 800 to completely remove any residual chemical liquid on the dummy substrate.

The liquid treating chamber 380 performs the development process by supplying a developer onto the substrate W and developing the substrate W. In addition, the liquid treating chamber 380 performs a wetting process in which a cleaning chemical liquid is applied to the dummy substrate DW for cleaning the drying chamber 600. The dummy substrate DW wet with the cleaning chemical liquid in the liquid treating chamber 380 is transferred to the drying chamber 600 by the transfer robot 351.

In FIG. 3 or FIG. 4, the transfer chamber 350 is provided with the transfer robot 351. The transfer robot 351 transfers the substrate W between the buffer unit 310, the cooling unit 320, the heat treating chamber 800, the drying chamber 600, the liquid treating chamber 380, and the buffer unit 510 or the cooling unit 520 of the interface module 500. In addition, the transfer robot 351 transfers dummy substrates between the buffer unit 310, the liquid treating chamber 380, the drying chamber 600, and the heat treating chamber 800.

In one example, the transfer robot 351 includes a hand 352 on which a substrate W or dummy substrate DW is placed. The hand 352 may be provided to be movable forward and backward, rotatable about the third direction 16 as the axis, and movable along the third direction 16. Within the transfer chamber 350, a guide rail 356 is provided with its longitudinal direction parallel to the first direction 12, and the transfer robot 351 may be movably provided on the guide rail 356.

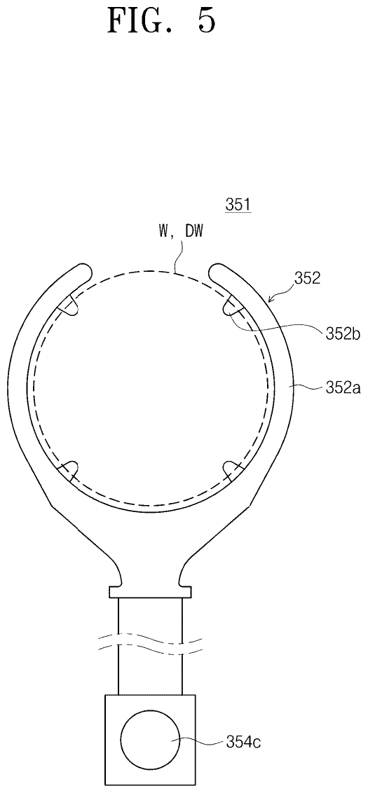

FIG. 5 is a diagram illustrating one example of a hand of the transfer robot. Referring to FIG. 5, the hand 352 includes a base 352a and a support protrusion 352b. The base 352a may have an annular ring shape in which a portion of the circumference is bent. The base 352a has an inner diameter greater than the diameter of the substrate W. The support protrusion 352b extends inwardly from the base 352a. A plurality of support protrusions 352b is provided, and supports an edge region of the substrate W. In one example, support protrusions 352b may be provided in four equally spaced rows.

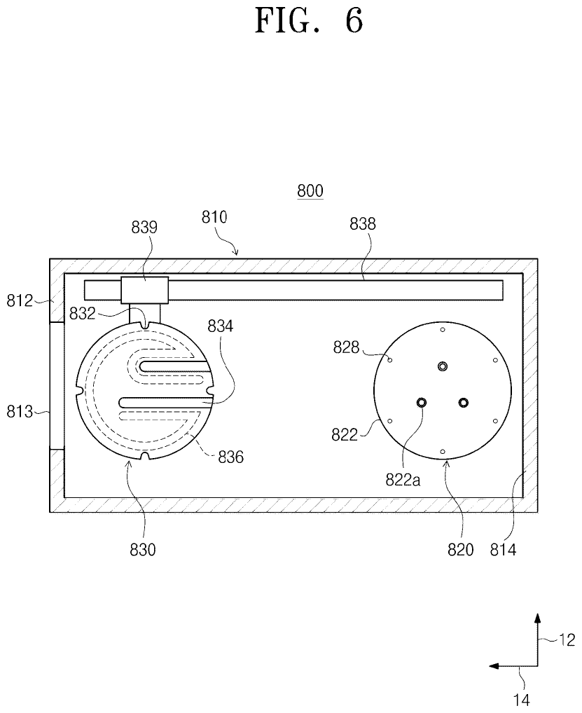

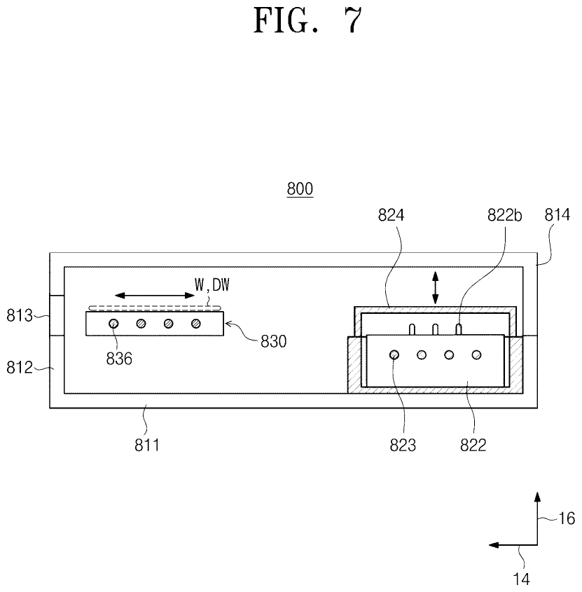

FIG. 6 is a top plan view schematically illustrating an example of the heat treating chamber of FIG. 3 or FIG. 4, and FIG. 7 is a front view of the heat treating chamber of FIG. 6. In the following, the heat treating chamber is described as a substrate heat treating apparatus. For reference, in FIG. 6, the cover of the heating unit has been omitted for convenience of illustration.

Referring to FIGS. 6 and 7, the heat treating chamber 800 may include a housing 810, a heating unit 820, and a transfer plate 830.

The housing 810 may include a bottom surface 811, a first lateral surface 812, and a second lateral surface 814. The first lateral surface 812 may be provided with an entrance opening 813 through which the substrate W enters and exits. The entrance opening 813 may be maintained in an open state. Optionally, a door (not illustrated) may be provided to open and close the entrance opening. The heating unit 820 and the transfer plate 830 may be provided within the housing 810. The second lateral surface 814 may be located to be in contact with a utility space.

The heating unit 820 may be provided adjacent to the second lateral surface. The heating unit 820 may include a bake plate 822 and a cover 824.

The bake plate 822 has a substantially circular shape when viewed from the top. The bake plate 822 has a diameter that is larger than the substrate W. The bake plate 822 transfers heat generated by the heater 823 to the substrate W. In one example, the heaters 823 may be printed patterns or heating wires that are heated by the supply of electrical power. The bake plate 822 may be provided in the shape of a circular plate. The top surface of the bake plate 822 has a larger diameter than the substrate. The top surface of the bake plate 822 functions as a seating surface on which the substrate W is placed. A plurality of lift holes 822a, vacuum holes 828, and proximate pins (not illustrated) are formed on the seating surface. The lift holes 822a and the vacuum holes 828 are located in different regions. Each of the lift holes 822a may be spaced apart from each other along the circumferential direction. A lift pin 822b may be located in each lift hole 822a. The lift pins 822b may be provided to be movable in an upward and downward direction along the third direction 16. The lift pin 822b may receive the substrate W from the transfer plate 830 and place the substrate W down on the bake plate 822, or lift the substrate W from the bake plate 822 and transfer the substrate to the transfer plate 830. In one example, three lift pins 822b may be provided.

The vacuum holes 828 may provide negative pressure between the seating surface and the edge of the substrate W. The warpage substrate may be flattened and secured to the bake plate 822 by the negative pressure provided through the vacuum holes 828. In one example, the vacuum holes 828 may be evenly arranged in an edge region of the seating surface. The vacuum holes 828 are connected to a vacuum pressure supply line 829. The vacuum pressure supply line 829 provides vacuum pressure to the vacuum holes 828. The vacuum pressure supply line 829 is connected to the capture module.

The cover 824 has a lower open space inside. The cover 824 is located on top of the bake plate 822 and is moved in an up and down direction by a driver (not illustrated). The space formed by the cover 824 and the bake plate 822 according to the movement of the cover 824 is provided as a heating space for heating the substrate W.

The transfer plate 830 is provided in a substantially disk shape, and has a diameter corresponding to that of the substrate W. A notch 830 is formed at the edge of the transfer plate 832. The notch 832 may have a shape that corresponds to the protrusion 352b formed on the hand 352 of the transfer robot 352 described above. Further, the notches 832 are provided in a number corresponding to the protrusions 352b formed on the hand, and are formed at positions corresponding to the protrusions 352b. In a position in which the hand and the transfer plate 830 are arranged in the vertical direction, the substrate W is transferred between the hand 352 and the transfer plate 830 when the vertical position of the hand and the transfer plate 830 is changed. The transfer plate 830 may be mounted on a guide rail 838 and may be moved along the guide rail 838 by the driver 839.

A plurality of slit-shaped guide grooves 830 is provided in the transfer plate 834. The guide groove 834 extends from the distal end of the transfer plate 830 to the inside of the transfer plate 830. The guide grooves 834 are provided along the second direction 14 in their longitudinal direction, and the guide grooves 834 are spaced apart from each other along the first direction 12. The guide groove 834 prevents the transfer plate 830 and the lift pin 822c from interfering with each other when a handover of the substrate W occurs between the transfer plate 830 and the heating unit 820.

The transfer plate 830 is provided of a thermally conductive material. According to an example, the transfer plate 830 may be made of a metal material.

A cooling flow path 830 is formed in the transfer plate 836. The cooling passage 836 is connected to the refrigerant supply line 837a, and the cooling passage 836 is supplied with coolant via the refrigerant supply line 837a. The substrate W, which has been completely heated in the heating unit 820, may be cooled while being transferred by the transfer plate 830. That is, the transfer plate 830 may function as a cooling unit to cool the substrate. Additionally, the substrate W may be cooled on the transfer plate 830 while waiting on the transfer plate 830 to be transferred to the transfer robot 351.

Although not illustrated, optionally, a cooling unit may additionally be provided within the housing 810. In this case, the cooling unit may be arranged in parallel with the heating unit 810. The cooling unit may be provided as a cooling plate having a passage formed therein through which coolant flows. The substrate that has been heated in the heating unit may be returned to the cooling unit for cooling.

Referring again to FIGS. 1 to 4, the interface module 500 connects the treating module 300 with an external exposure device 700. The interface module 500 includes an interface frame 501, a buffer unit 510, a cooling unit 520, a transfer mechanism 530, an interface unit 540, and an additional process chamber 560.

The top end of the interface frame 501 may be provided with a fan filter unit forming a downward airflow therein. The buffer unit 510, the cooling unit 520, the transfer mechanism 530, the interface unit 540, and the additional process chamber 560 are disposed inside the interface frame 501.

The structure and arrangement of the buffer unit 510 and the cooling unit 520 may be the same or similar to those of the buffer unit 310 and the cooling unit 320 provided in the treating module 300. The buffer unit 510 and the cooling unit 520 are disposed adjacent to the end of the transfer chamber 350. The substrate W transferred between the treating module 300, the cooling unit 520, the additional process chamber 560, and the exposure device 700 may temporarily stay in the buffer unit 510. The cooling unit 520 may be provided only at a height corresponding to the application block 300a between the application block 300a and the developing block 300b.

The transfer mechanism 530 may transfer the substrate W between the buffer units 510. The transfer mechanism 530 may also transfer the substrate W between the buffer unit 510 and the cooling unit 520. The transfer mechanism 530 may be provided with the same or similar structure as the transfer mechanism 330 of the treating module 300. Another transfer mechanism 531 may be further provided in a region opposite the region where the transfer mechanism 530 is provided with respect to the buffer unit 510.

The interface robot 540 is disposed between the buffer unit 510 and the exposure device 700. The interface unit 540 is provided to transfer the substrate W between the buffer unit 510, the cooling unit 520, the additional process chamber 560, and the exposure device 700. The interface unit 540 includes a hand 542 on which the substrate W is placed, and the hand 542 may be provided to be movable forward and backward, rotatable about the axis parallel to the third direction 16, and movable along the third direction 16.

The additional process chamber 560 may perform a predetermined additional process before the substrate W processed in the applying block 300a is loaded to the exposure device 700. Optionally, the additional process chamber 560 may perform a predetermined additional process before the substrate W processed in the exposure device 700 is loaded to the developing block 300b. In one example, the additional process may be an edge exposure process that exposes an edge region of the substrate W, or a top surface cleaning process that cleans the top surface of the substrate W, or a bottom surface cleaning process that cleans the bottom surface of the substrate W, or an inspection process that performs a predetermined inspection on the substrate W. A plurality of additional process chambers 560 may be provided, which may be stacked on top of each other.

Hereinafter, the structure of the liquid treating chamber will be described in detail. The liquid treating chamber provided in the applying block 300a is described below as an example. In addition, the liquid treating chamber will be described based on the case of a chamber for applying the photoresist onto the substrate as an example.

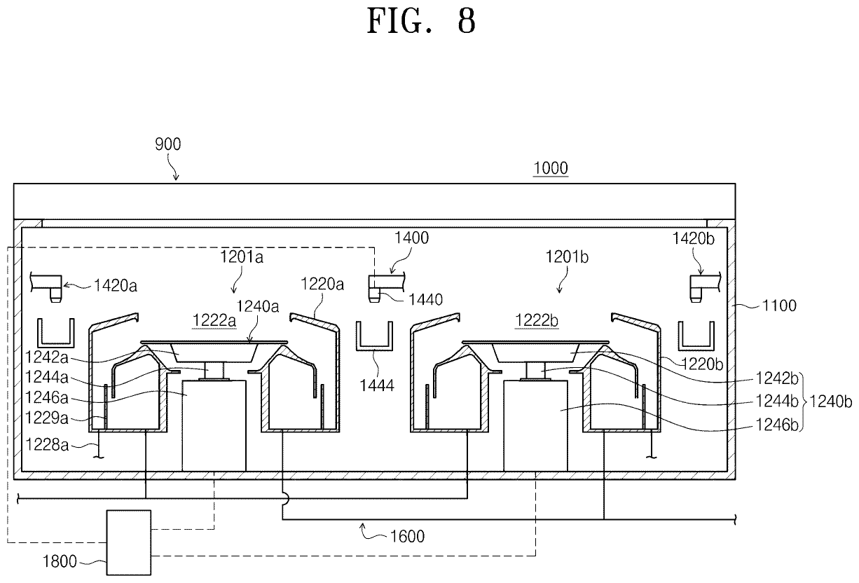

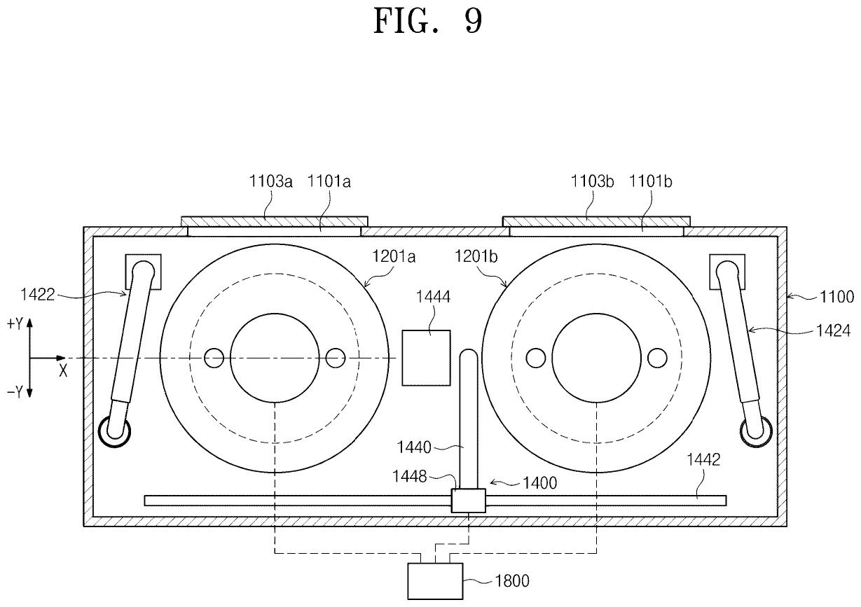

FIG. 8 is a cross-sectional view illustrating an exemplary embodiment of a liquid treating chamber, and FIG. 9 is a top view of the liquid treating chamber of FIG. 8.

Referring to FIGS. 8 and 9, the liquid treating chamber 1000 includes a housing 1100, a first treating unit 1201a, a second treating unit 1201b, a liquid supply unit 1400, an exhaust unit 1600, and a controller 1800.

The housing 1100 is provided in a rectangular cylindrical shape having an interior space. Openings 1101a and 1101b are formed at one side of the housing 1100. The openings 1101a and 1101b function as passages through which the substrate W is loaded in and out. Doors 1103a and 1103b are installed in the openings 1101a and 1101b, and the doors 1103a and 1103b open and close the openings 1101a and 1101b.

On the upper wall of the housing 1100, an air conditioning device 900 having a filter box that supplies downflow airflow to the interior space thereof is disposed. The air conditioning device 900 has a filter that introduces air from the outside into the interior space and filters the air. The air conditioning device 900 has another chamber arranged in the upper portion, which is directly subjected to temperature influence generated by the temperature of a heating element (motor, heater, and the like) in the surrounding area. The air conditioning device 900 of the present invention has a structure that is capable of minimizing the temperature influence of the surrounding area.

The first treating unit 1201a and the second treating unit 1201b are provided in the interior space of the housing 1100. The first treating unit 1201a and the second treating unit 1201b are arranged along one direction.

The first treating unit 1201a has a first treating container 1220a and a first support unit 1240a.

The first treating container 1220a has a first interior space 1222a. The first interior space 1222a is provided with an open top.

The first support unit 1240a supports the substrate W in the first interior space 1222a of the first treating container 1220a. The first support unit 1240a includes a first support plate 1242a, a first driving shaft 1244a, and a first driver 1246a. The first supporting plate 1242a has a circular top surface. The first support plate 1242a has a smaller diameter than that of the substrate W. The first support plate 1242a is provided to support the substrate W by vacuum pressure. Optionally, the first support plate 1242a may have a mechanical clamping structure for supporting the substrate W. A first driving shaft 1244a is coupled to the center of the bottom surface of the first support plate 1242a, and a first driver 1246a for providing rotational force to the first driving shaft 1244a is provided to the first driving shaft 1244a. The first driver 1246a may be a motor. The second treating unit 1201b includes a second treating container 1220b and a second support unit 1240b, and the second support unit 1240b includes a second support plate 1242b, a second driving shaft 1244b, and a second driver 1246b. The second treating container 1220b and the second supporting unit 1240b have substantially the same structure as the first treating container 1220a and the first supporting unit 1240a.

The liquid supply unit 1400 supplies the liquid onto the substrate W. The liquid supply unit 1400 includes a first nozzle 1420a, a second nozzle 1420b, and a treatment solution nozzle 1440. The first nozzle 1420a supplies a liquid to the substrate W provided to the first support unit 1240a, and the second nozzle 1420b supplies a liquid to the substrate W provided to the second support unit 1240b. The first nozzle 1420a and the second nozzle 1420b may be provided to supply the same type of liquid. According to the example, the first nozzle 1420a and the second nozzle 1420b may supply a rinse liquid for cleaning the substrate W. For example, the rinse liquid may be water. According to another example, the first nozzle 1420a and the second nozzle 1420b may supply a removal liquid for removing the photoresist from the edge region of the substrate W. For example, the removal liquid may be a thinner. Each of the first nozzle 1420a and the second nozzle 1420b may be rotated between a process position and a standby position about a rotation shaft thereof. The process position is a position at which the liquid is discharged onto the substrate W, and the standby position is a position at which the first nozzle 1420a and the second nozzle 1420b stand by without discharging the liquid onto the substrate W.

The treatment solution nozzle 1440 supplies the treatment solution to the substrate W provided to the first support unit 1240a and the substrate W provided to the second support unit 1240b. The treatment solution may be a photoresist. The nozzle driver 1448 drives the treatment solution nozzle 1440 so that the treatment solution nozzle 1440 moves between a first process position, the standby position, and a second process position along a guide 1442. The first process position is a position for supplying the treatment solution to the substrate W supported by the first support unit 1240a, and the second process position is a position for supplying the treatment solution to the substrate W supported by the second support unit 1240b. The standby position is a position in which the nozzle waits the standby port 1444 located between the first treating unit 1201a and the second treating unit 1201b when the photoresist is not discharged from the treatment liquid nozzle 1440.

A gas-liquid separation plate 1229a may be provided in the interior space 1201a of the first treating container 1220a. The gas-liquid separation plate 1229a may be provided to extend upwardly from the bottom wall of the first treating container 1220a. The gas-liquid separation plate 1229a may be provided in a ring shape.

According to the example, the outside of the gas-liquid separation plate 1229a may be provided as a discharging space for discharging the liquid, and the inside of the gas-liquid separation plate 1229a may be provided as an exhaust space for exhausting the atmosphere. A discharge pipe 1228a for discharging the treatment solution is connected to the bottom wall of the first treating container 1220a. The discharge pipe 1228a discharges the treatment solution introduced between the sidewall of the first treating container 1220a and the gas-liquid separation plate 1229a to the outside of the first treating container 1220a. The airflow flowing into the space between the sidewall of the first treating container 1220a and the gas-liquid separation plate 1229a is introduced into the gas-liquid separation plate 1229a. In this process, the treatment solution contained in the airflow is discharged from the discharging space to the outside of the first treating container 1220a through the discharge pipe 1228a, and the airflow is introduced into the exhaust space of the first treating container 1220a.

Although not illustrated, a lift driver for adjusting the relative height of the first support plate 1242a and the first treating container 1220a may be provided.

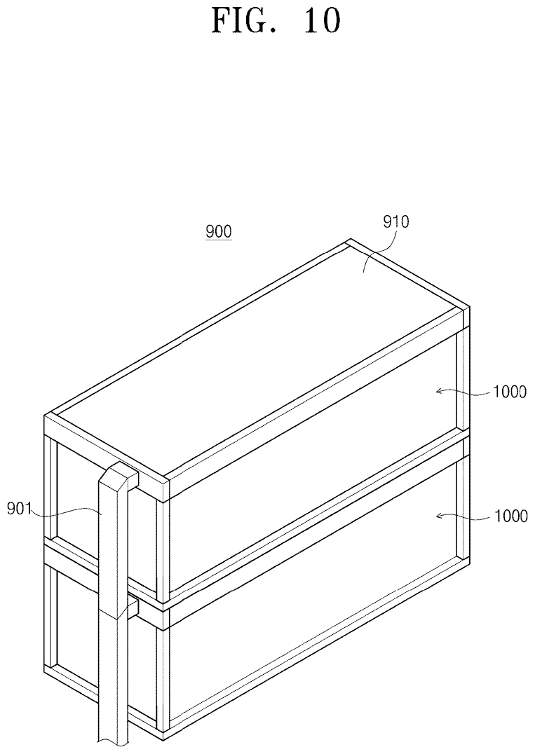

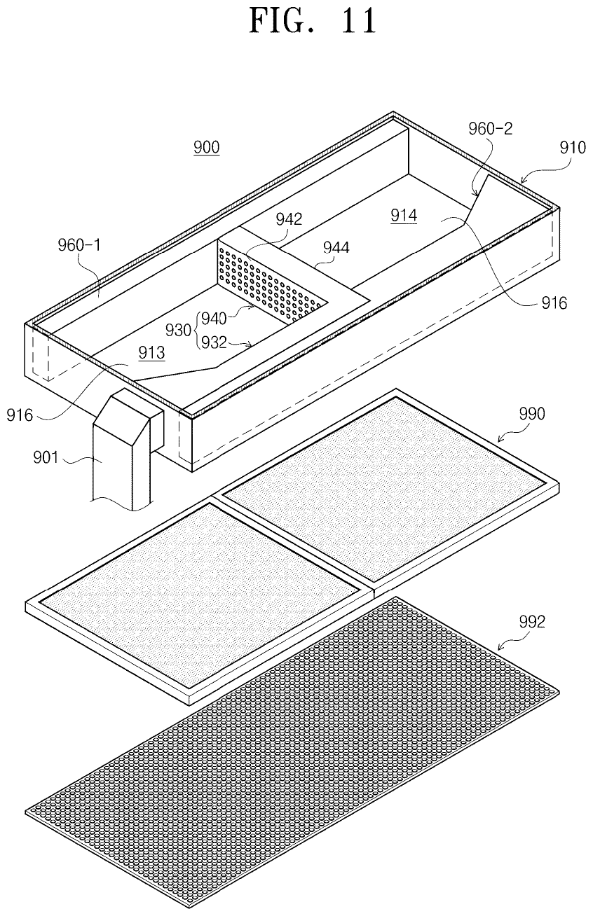

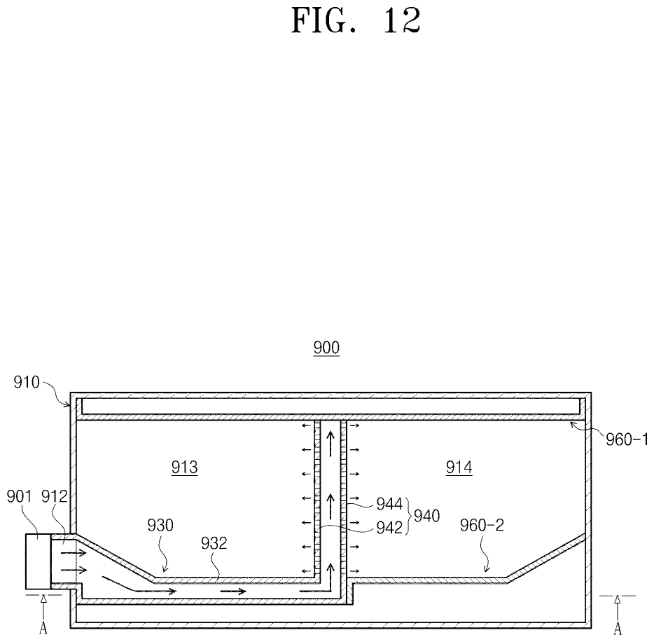

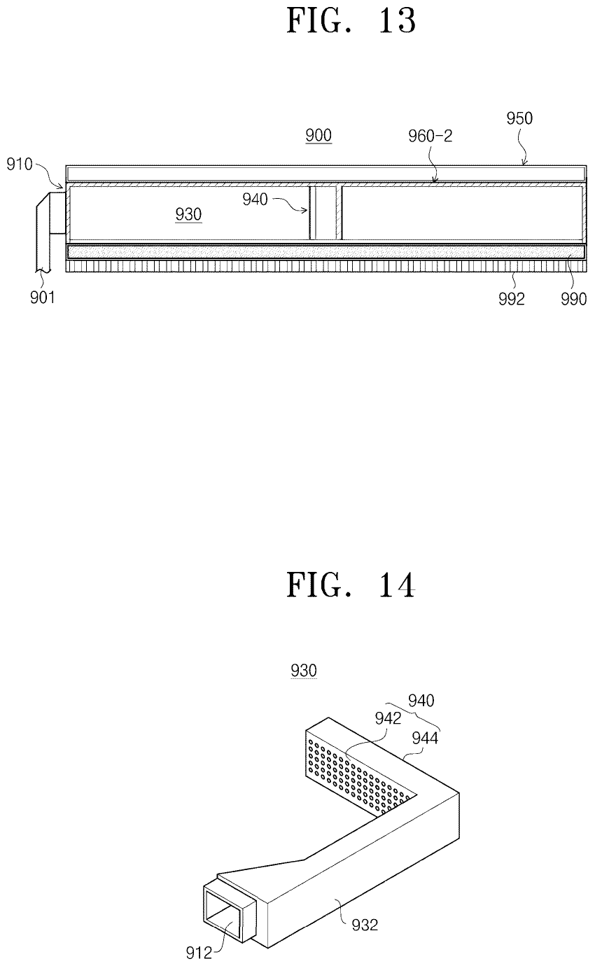

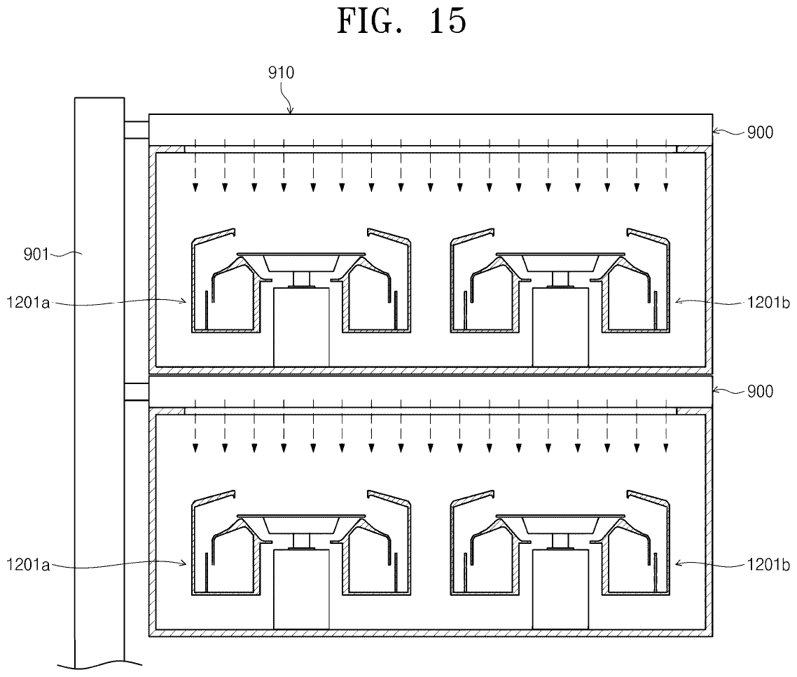

FIG. 10 is a perspective view illustrating an example of the air conditioning devices installed in stacked liquid treating chambers, FIG. 11 is a perspective view of the air conditioning device illustrated in FIG. 10, FIGS. 12 and 13 are a top plan view and a lateral cross-sectional view of the air conditioning device, and FIG. 14 is a perspective view of an internal duct illustrated in FIG. 12. FIG. 15 is a lateral cross-sectional view illustrating an example of the air conditioning devices installed in stacked liquid treating chambers.

Referring to FIGS. 10 to 15, the air conditioning device 900 may include a case 910, an internal duct 930, a top air pocket 950, side air pockets 960-1 and 960-2, a filter 990, and a perforated plate 992.

The case 910 is formed with interior spaces 913 and 914 that allow air injected therein to diffuse. The interior spaces 913 and 914 may be divided into a first space 913 and a second space 914 by a central duct 930 of the internal duct 930. The first space 913 and the second space 914 have symmetrical spaces from side to side with respect to the central duct. To this end, the air pocket 960-2 of the side air pocket 960-1 and 960-2 have a shape corresponding to the shape of the internal duct 930. Below the first space 913, the first treating unit 1201a of the liquid treating chamber is positioned, and below the second space 914, the second treating unit 1201b is positioned. As such, the first space 913 and the second space 914 have a symmetrical structure, so that the air conditioning device 900 may provide uniform down airflow to the first treating unit 1201a and the second treating unit 1201b.

As illustrated in FIG. 13, the upper air pocket 950 may be provided in an upper portion of the case 910. The upper air pocket 950 blocks the temperature influences of heating elements (motors, drives, and the like) of another liquid treating chamber located above the air conditioning device 900.

The case 910 may have a box shape including a bottom portion, lateral walls extending perpendicular to the bottom portion from opposing ends of the bottom portion, and a lid covering the lateral walls. The case 910 may be provided with an area equal to or larger than the area occupied by the two treating units disposed along the first direction of the liquid treating chamber 1000. The case 910 may be disposed on top of the liquid treating chamber 1000.

In the exemplary embodiment of the present invention, one side of the case 910 has an inlet 912 through which air is introduced.

The inlet 912 of the case 910 receives air via a supply duct 901. The supply duct 901 supplies air to each of the air conditioning devices 900 of the multi-stacked liquid treating chambers 1000. Dampers (not illustrated) are installed in the supply duct 901, which regulate the air flow rate to the air conditioning device 900.

The bottom of the case 910 has an opening 916 for downflow of air introduced into the first and second spaces 913 and 914. A plate-shaped filter 990 is installed in the opening 916. On the lower side of the filter 990, the perforated plate 992 is installed.

The internal duct 930 guides air from the inlet 912 to the center of the case 910 such that the air introduced through the inlet 912 is uniformly supplied to the interior space of the case 910. The internal duct 930 may include a central duct 940 and a connection duct 932 connecting the central duct 940 to the inlet 912. The central duct 940 divides the interior space of the case 910 into the first space 913 and the second space 914. The central duct 940 has a structure that may supply air to the first space 913 and the second space 914. The central duct 940 may include a first partition wall 942 that is in contact with the first space 913 and a second partition wall 944 that is in contact with the second space 914. The first partition wall 942 and the second partition wall 944 are made of perforated plates.

In the air conditioning device 900, air introduced through the inlet 912 is guided through the internal duct 930 to the center of the case 910 and then supplied to the left and right spaces 913 and 914. Thus, uniform down airflow may be provided to the first treating unit 1201a and the second treating unit 1201b.

In particular, by providing the air pockets 950, 960-1, and 960-2 on the upper surface and both lateral surfaces of the case 910, the air conditioning device 900 may block heat transferred from the surroundings (the chamber located at the top of the air conditioning device) to provide airflow with a uniform temperature to the liquid treating chamber 1000. Thus, the temperature deviation around the first treating unit 1201a and the second treating unit 1201b may be significantly reduced.

As described above, the air conditioning device 900 of the present invention, air is supplied from the center of the case to the first and second spaces and flows downwardly into the liquid treating chamber, and especially the top surface and the lateral surfaces of the case are thermally insulated with air pockets, so that it may be expected to equalize the temperature when air is supplied to the liquid treating chamber.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. An air conditioning device for providing downward airflow from an upper portion of a process chamber having a treatment space in which a first treating unit and a second treating unit are disposed side by side to the treatment space, the air conditioning device comprising:
a case having an inlet through which air is introduced at one side, and having an opening at a lower surface for the air introduced through the inlet to flow downwardly; and
an internal duct for guiding air from the inlet to a center of the case such that the air introduced through the inlet is uniformly supplied to an interior space of the case.

2. The air conditioning device of claim 1, wherein the internal duct includes a central duct dividing the interior space of the case into a first space and a second space and supplying air to the first space and the second space.

3. The air conditioning device of claim 2, wherein the central duct includes a first partition wall that is in contact with the first space and a second partition wall that is in contact with the second space, and
the first partition wall and the second partition wall are made of perforated plates.

4. The air conditioning device of claim 2, wherein the first space is located on top of the first treating unit, and
the second space is located on top of the second treating unit.

5. The air conditioning device of claim 2, wherein the first space and the second space have spaces symmetric with respect to the central duct.

6. The air conditioning device of claim 2, further comprising:
an upper air pocket provided on a top surface of the case.

7. The air conditioning device of claim 2, further comprising:
lateral air pockets provided on both lateral surfaces of the case.

8. The air conditioning device of claim 2, further comprising:
a plate-shaped filter installed in the opening; and
a perforated plate installed at a bottom end of the filter.

9. A substrate treating apparatus comprising:
a chamber having a treatment space;
a first treating unit and a second treating unit arranged in line along a first direction in the treatment space of the chamber; and
an air conditioning device installed in an upper portion of the chamber, and providing downflow airflow into the treatment space of the chamber,
wherein the air conditioning device includes:
a case having an inlet through which air is introduced at one side, and having an opening at a lower surface for the air introduced through the inlet to flow downwardly; and
an internal duct for guiding the air from the inlet to a center of the case such that the air introduced through the inlet is uniformly supplied to an interior space of the case.

10. The substrate treating apparatus of claim 9, wherein the internal duct includes a central duct dividing the interior space of the case into a first space and a second space and supplying air to the first space and the second space.

11. The substrate treating apparatus of claim 10, wherein the central duct includes a first partition wall that is in contact with the first space and a second partition wall that is in contact with the second space, and
the first partition wall and the second partition wall are made of perforated plates.

12. The substrate treating apparatus of claim 11, wherein the first space is located on top of the first treating unit, and
the second space is located on top of the second treating unit.

13. The substrate treating apparatus of claim 10, wherein the first space and the second space have spaces symmetric with respect to the central duct.

14. The substrate treating apparatus of claim 10, further comprising:
an upper air pocket provided on a top surface of the case.

15. The substrate treating apparatus of claim 10, further comprising:
lateral air pockets provided on both lateral surfaces of the case.

16. The substrate treating apparatus of claim 10, further comprising:
a plate-shaped filter installed in the opening; and
a perforated plate installed at a bottom end of the filter.

17. The substrate treating apparatus of claim 10, wherein the first treating unit and the second treating unit apply a liquid to the substrate.

18. The substrate treating apparatus of claim 10, wherein the chambers are staked in plural.

19. A substrate treating apparatus comprising:
a chamber having a treatment space;
a first treating unit and a second treating unit arranged in line along a first direction in the treatment space of the chamber, and applying a liquid to a substrate; and
an air conditioning device installed in an upper portion of the chamber, and providing downflow airflow into the treatment space of the chamber,
wherein the air conditioning device includes:
a case having an inlet through which air is introduced at one side, and having an opening at a lower surface for the air introduced through the inlet to flow downwardly;
an internal duct for guiding the air from the inlet to a center of the case such that the air introduced through the inlet is uniformly supplied to an interior space of the case;
a plate-shaped filter installed in the opening;
a perforated plate installed at a bottom end of the filter;
an upper air pocket provided on a top surface of the case; and
lateral air pockets provided on both lateral surfaces of the case, and
the internal ducting includes a central duct that divides the interior space of the case into a first space located on top of the first treating unit and a second space located on top of the second treating unit and that supplies air to the first space and the second space.

20. The substrate treating apparatus of claim 19, wherein the central duct includes a first partition wall that is in contact with the first space and a second partition wall that is in contact with the second space,
the first partition wall and the second partition wall are made of perforated plates, and
the first space and the second space have spaces symmetric with respect to the central duct.
